(19) United States
(12) Patent Application Publication
(10) Pub. No.: US 2017/0336467 A1
(43) Pub. Date: Nov. 23, 2017

(54) GATE PROTECTION FOR HV-STRESS APPLICATION

(71) Applicant: GLOBALFOUNDRIES Inc., Grand Cayman (KY)

(72) Inventors: Ricardo Pablo. Mikalo, Heideblick (DE); Stefan Richter, Moritzburg (DE); Christian Schippel, Dresden (DE); Michael Zier, Dresden (DE)

(21) Appl. No.: 15/156,814

(22) Filed: May 17, 2016

(51) Int. Cl. G01R 31/26; H01L 27/12; H01L 23/528; H01L 23/525; H01L 21/84; H01L 27/092; H01L 29/78

(52) U.S. Cl. CPC G01R 31/2621; H01L 23/5256; H01L 27/1203; H01L 21/84; H01L 23/528; H01L 29/78; H01L 27/092

(57) ABSTRACT

A test structure for a semiconductor device, comprising a device under test including a transistor, the transistor having a gate electrode, a source electrode, a drain electrode and a bulk electrode, a first fuse and a second fuse provided in series, wherein one terminal of the first fuse is connected to the gate electrode, one terminal of the second fuse is connected to the bulk electrode, the other terminal of the first fuse and the other terminal of the second fuse being connected to each other, a first input/output pad connected to the first terminal of the first fuse and to the gate electrode of the transistor, a second input/output pad connected to the first terminal of the second fuse and to the bulk electrode of the transistor, a third input/output pad connected to the second terminal of the first fuse and the second terminal of the second fuse.

### BACKGROUND OF THE INVENTION

### 1. Field of the Invention

Generally, the present disclosure relates to the field of integrated circuits and semiconductor devices and, more particularly, to gate protection for HV-stress application for SOI devices.

### 2. Description of the Related Art

The fabrication of advanced integrated circuits, such as CPUs, storage devices, application specific integrated circuits (ASICs) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors (FETs), wherein, for many types of complex circuitry, metal-oxide-semiconductor (MOS) technology is currently one of the most promising approaches due to the superior characteristics in view of operating speed and/or power consumption and/or cost efficiency. During the fabrication of complex integrated circuits using, for instance, complementary MOS (CMOS) technology, millions of N-channel transistors and P-channel transistors are formed on a substrate including a crystalline semiconductor layer.

A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed between the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length is a dominant design criterion for accomplishing an increase in the operating speed of the integrated circuits. As the channel length is reduced, the thickness of the gate dielectric is also reduced. The scaling of the gate dielectric is limited by several factors, such as defects, power supply voltage, time-dependent dielectric breakdown and leakage currents.

Typically, metal gate CMOS transistors are developed for low-voltage applications, such as processors and system on chip (SoC) devices. But these devices are connected to the outside world and require input/output (I/O or IO) transistors that support higher bias voltages. Modern technologies particularly require high performance transistors. Such high performance transistors typically require shallow source/drain (S/D) implants. IO transistors are typically formed using the same S/D implants. These S/D implants exhibit breakdown voltages in the range of 6-9 V. This is sufficient for operation, since typical IO voltages range today from 1.8 V to 2.5 V or 3.3 V. However. IO devices carrying these IO transistors must have thicker gate oxide layers so that the devices can operate at the higher IO voltages.

However plasma-induced damages of gate dielectrics, such as so-called antenna effects, occurring during the overall processing of the semiconductor devices pose severe problems and may significantly affect yield and reliability of the semiconductor devices. The damages comprise plasma charging damages that particularly occur when electrical charges are collected from the plasma by the gate electrode and flow through the gate dielectric. For example, the antenna effect is caused by polysilicon, metal or contact etching and ion implantation. During manufacturing, gate protection diodes may be used in order to prevent damage of the gate oxides due to plasma processes, namely mainly etch processes. For example, this particularly applies for back end of line (BEOL), which is the second portion of integrated circuit (IC) fabrication. Here the individual devices, such as transistors, capacitors, resistors, etc., get interconnected with wiring on the wafer, e.g., the metallization layer. Common metals are copper interconnect and aluminum interconnect. BEOL processing is a stage of processing that is generally understood to begin when the first layer of metal is deposited on the wafer. BEOL processing includes formation of contacts, insulating layers, e.g., dielectrics, metal levels, and bonding sites for chip-to-package connections. These gate protection diodes are active elements connected in parallel to the transistor gate-to-bulk connection. The realization of these protection diodes is commonly done with the S/D diodes as standalone elements. Consequently, there can be no higher voltages applied to transistor gates as is defined by the breakdown voltage of the protection diodes.

Commonly, for testing the above devices, electrical test structures are used. Electrical test structures are not only used for electrical parameter determination, but are also used for establishing reliability assessments which are required for monitoring such devices. One possibility for test measurements is to directly contact the test structure on a silicon wafer. Another possibility is to conduct the measurements after dicing and packaging of the test structure.

A device under test (DUT) is a die on a wafer or the resulting packaged part, a circuit element or block to be characterized by the test measurements. A DUT may also include a number of these circuit elements and blocks connected together to form a single unit, such as an array of MOSFETs. A test structure includes a DUT and a peripheral circuitry required for carrying out the test measurements. A macro test structure or macro may include one or more test structures. Test structures within a macro may share peripheral circuits and I/O pads to improve silicon area utilization and test efficiency.

This is shown in FIG. 1. In FIG. 1, a conventional test structure 100 is shown. The test structure 100 comprises a device under test 103. The device under test shown in FIG. 1 is a MOSFET 103, having the respective S, G, D and B terminals corresponding to Source, Gate, Drain and Body/Bulk. Often, terminal B is connected to S, thereby having a relative voltage between B and S of V_{BS}=0, and consequently only S, G and D are used to represent the terminals.

FIG. 1 further illustrates a diode 101 for protecting the DUT 103. The diode 101 may serve as preventing plasma-induced damage (PID). Further, FIG. 1 shows two contact pads 105 serving as I/O pads for the test structure 100. The contact pads 105 may be of some conducting areas. A different possibility would be to provide solder bumps (not shown) instead of the contact pads 105. The contact pads may be contacted manually by applying bent or cantilevered probes, e.g., needle-shaped contacts (not shown here). Thus the contact will exist only as long as a user contacts the contact pads 105 with the probes, i.e., as long as the needle-shaped contacts land on the contact pads.

However, the test structure 100 may also be interfaced with some testing equipment provided on a testing area, as shown in FIG. 2. In FIG. 2, for explanatory purposes only, a test structure area 113 comprises a macro-like rectangular area 115 including two test structures 100 and 100a. Test structure 100 may be the same test structure as shown in FIG. 1. Test structure 100a may be the same as test structure 100 or may differ from it. Details of test structure 100a are not shown here but it is merely shown as one possible geometrical arrangement of test structure 100a with respect to test structure 100. Test structure 100 includes DUT 103 as already illustrated in FIG. 1. As an example, the macro-like area 115 includes contacting pads 105 which may be substantially the same as shown in FIG. 1. For explanatory purposes only, contacting pads 105 are connected by an interface 111 to test equipment 109 which is provided on testing area 107. Test equipment 109 may include standard test equipment for performing electrical measurements.

In principle, DUTs such as the ones shown in FIGS. 1 and 2 may be placed at each metal level of a stack of metal layers.

In order to obtain reasonable measurement times, the reliability investigation makes use of voltage acceleration. Voltage acceleration typically includes higher voltages which are to be applied to the respective gates of the transistors of the IO devices. This is also called a stress test. For such stress tests, so-called overvoltages are applied, which are, e.g., surges, fast, short duration electrical transients. These overvoltages to be used for the stress tests may need to have different magnitudes depending upon the devices to be tested. For logic transistors, the required overvoltages are relatively small, i.e., ranging from 4-5 V for a 1.0 V transistor. However, the overvoltages required for 3.3 V transistors rather range in the region of 13-15 V in order to achieve reasonable voltage acceleration factors.

This is shown in FIG. 3 which illustrates the problem that arises when the above-mentioned voltage ranges are to be used. Whereas it is possible to achieve the required overvoltages for tests for a SG logic device, e.g., including a 1.0 V transistor (see the leftmost device drawn on the horizontal axis of FIG. 3), the difficulty for other devices increases. For a 1.8 V EG I/O device (see the second device counting from the left in FIG. 3), overvoltages already closely approach the protection diode breakdown, putting the protection diode in jeopardy. Moreover, for a 2.5 V ZG I/O device (see the third device drawn from the left in FIG. 3), the required overvoltages already exceed the protection diode breakdown voltage. Finally, for the fourth example shown in FIG. 3, a 3.3 V I/O device, the desired overvoltages for testing clearly exceed the protection diode breakdown line. Here, SG denotes the standard gate oxide, which typically has electrical Tₒₓ (thickness of oxide) inversion thickness values around 20-24 Å (0.20-0.24 nm). EG denotes a thicker gate oxide, which typically has electrical T_{OX} inversion thickness values around 30-35 Å (0.30-0.35 nm). ZG denotes an even thicker gate oxide for higher I/O voltages, which typically has electrical T_{OX} inversion thickness values around 56-58 Å (0.56-0.58 nm). Finally, a 3.3 V I/O device is an I/O device having even thicker gate oxides than any of SG, EG, ZG. For 3.3 V I/O devices, typically electrical T_{OX} inversion thickness values around 72-78 Å (0.72-0.78 nm) are used.

In view of the above requirements for selecting the appropriate stress overvoltages for the transistors and possible other DUTs to be tested, the problem arises that the gate protection diodes do not allow such high stress overvoltage application when applied to the DUTs, e.g., the gate protection diodes may be destroyed by applying the stress overvoltages.

Therefore, and in view of the most recent 22FDX technology, there is a need of finding an alternative solution for protecting the test structures.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to test structures for a semiconductor device including a device under test including a transistor, the transistor having a gate electrode, a source electrode, a drain electrode and a bulk electrode, a first fuse and a second fuse provided in series, wherein one terminal of the first fuse is connected to the gate electrode, one terminal of the second fuse is connected to the bulk electrode, the other terminal of the first fuse and the other terminal of the second fuse being connected to each other, a first input/output pad connected to the first terminal of the first fuse and to the gate electrode of the transistor, a second input/output pad connected to the first terminal of the second fuse and to the bulk electrode of the transistor, a third input/output pad connected to the second terminal of the first fuse and the second terminal of the second fuse. It should be understood that the terms input/output pad, contact pad and contacting pad are used synonymously throughout this text.

The subject matter disclosed herein also relates to a fuse for test structures in integrated semiconductor technology, including a symmetrical body having two terminals each of a maximum width of 100-500 nm, the terminals connected by a melting wire, the melting wire having a thickness or diameter of 20-1000 nm and the melting wire having a length of 0.1-10 μm. It should be understood that, while the 22FDX technology may be a prominent example for an integrated semiconductor technology for applying the present disclosure, the present disclosure is not limited to 22FDX technology, but instead may be applied in all integrated semiconductor technologies.

The subject matter disclosed herein also relates to a semiconductor device with a test structure including a power line, a silicon-on-insulator (SOI) substrate comprising a semiconductor layer and a semiconductor bulk substrate comprising a doped region, a transistor formed in and above the SOI substrate and comprising a gate dielectric formed over the semiconductor layer and a gate electrode formed over the gate dielectric, the transistor having a gate electrode, a source electrode, a drain electrode and a bulk electrode, wherein the test structure includes a device under test including the transistor, a first fuse and a second fuse provided in series, wherein one terminal of the first fuse is connected to the gate electrode, one terminal of the second fuse is connected to the bulk electrode, the other terminal of the first fuse and the other terminal of the second fuse being connected to each other, a first input/output pad connected to the first terminal of the first fuse and to the gate electrode of the transistor, a second input/output pad connected to the first terminal of the second fuse and to the bulk electrode of the transistor, and a third input/output pad connected to the second terminal of the first fuse and the second terminal of the second fuse.

The subject matter disclosed herein also relates to a method of manufacturing a semiconductor device with a test structure including providing a silicon-on-insulator (SOI)) semiconductor substrate comprising a semiconductor layer and a semiconductor bulk substrate comprising a doped region, forming a transistor in and above the SOI substrate, the transistor comprising a gate dielectric formed over the semiconductor layer and a gate electrode formed over the gate dielectric, the transistor having a gate electrode, a source electrode, a drain electrode and a bulk electrode, providing the test structure including a device under test including the transistor, providing a first fuse and a second fuse in series, connecting one terminal of the first fuse to the gate electrode, connecting one terminal of the second fuse to the bulk electrode, connecting the other terminal of the first fuse and the other terminal of the second fuse to each other, providing a first input/output pad connected to the first terminal of the first fuse and to the gate electrode of the transistor, providing a second input/output pad connected to the first terminal of the second fuse and to the bulk electrode of the transistor, and providing a third input/output pad connected to the second terminal of the first fuse and the second terminal of the second fuse.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates an example of a test structure (prior art);

FIG. 2 illustrates a configuration including a test structure interfaced with testing equipment on a testing area;

FIG. 3 illustrates desired overvoltages for reliability tests for a set of different devices;

FIG. 4 illustrates a modified test structure according to an example of the present disclosure;

FIG. 5 illustrates a fuse for a modified test structure according to an example of the present disclosure; and

FIGS. 6A-6D illustrate applying stress testing to the test structure of FIG. 4 according to the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the disclosure. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc. The techniques and technologies described herein may be utilized to fabricate MOS integrated circuit devices, including NMOS integrated circuit devices, PMOS integrated circuit devices and CMOS integrated circuit devices. The application of the disclosed protection may be applied in particular but is not limited to transistor DUTs, capacitor DUTs, metal-oxide-metal capacitor DUTs inversion capacitor DUTs, comb-meander test structure DUTs, etc.

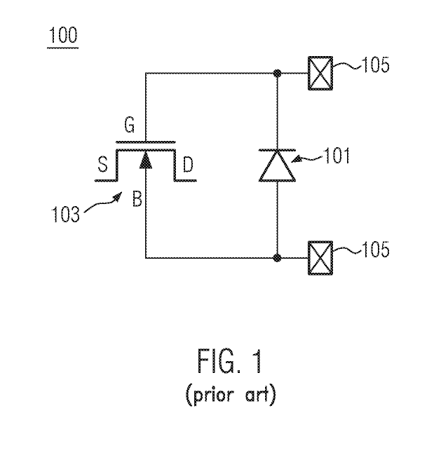

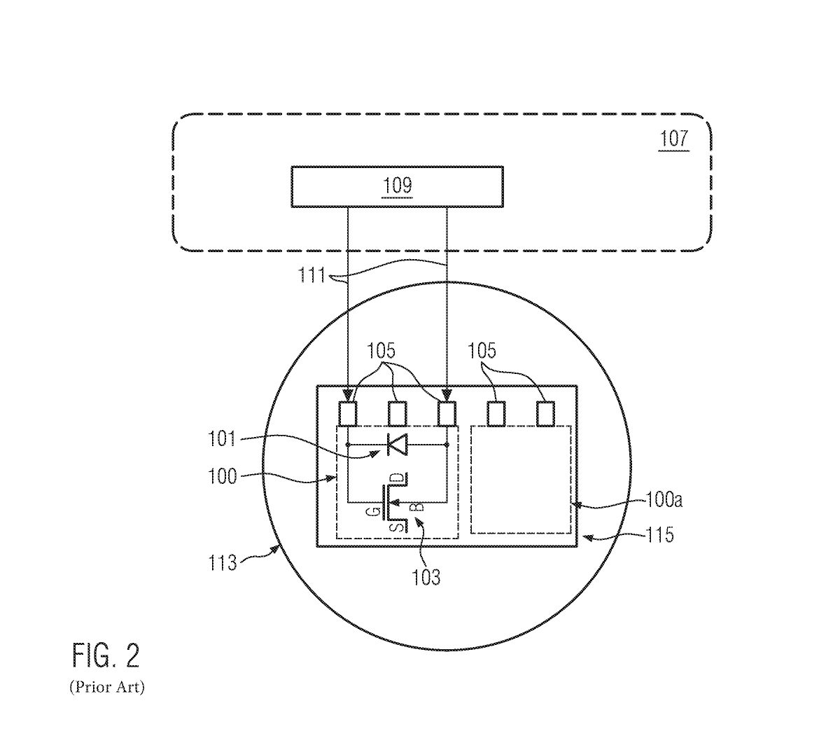

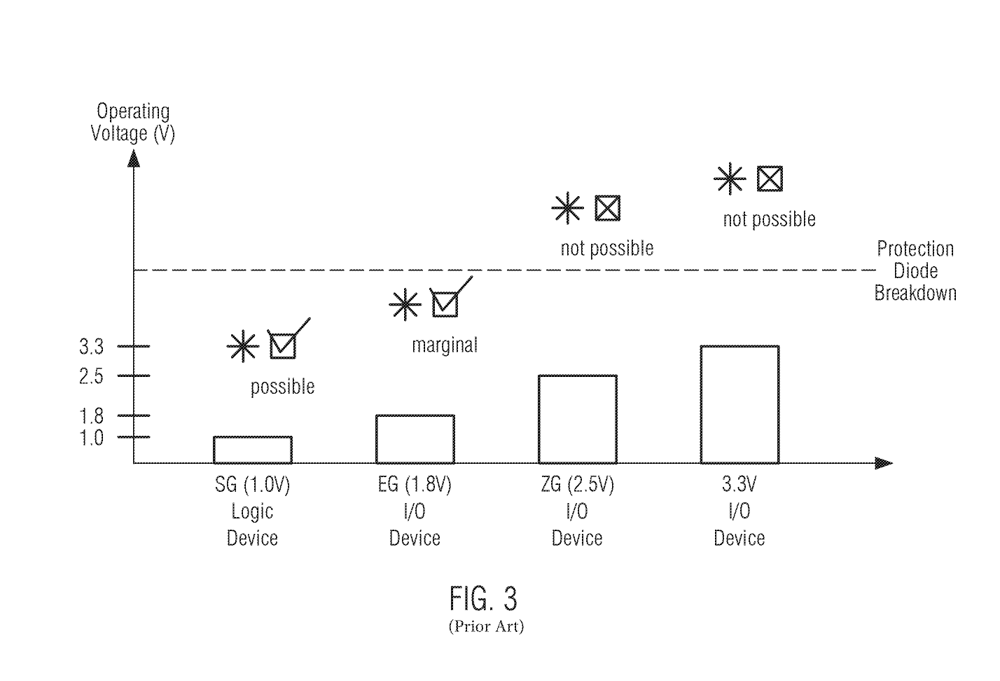

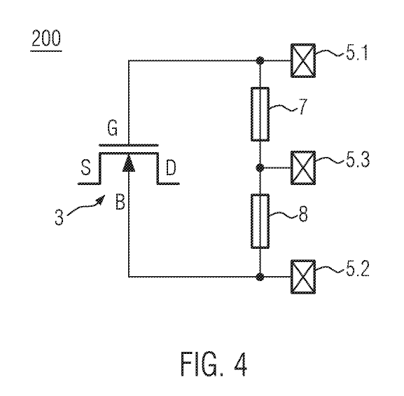

In view of the problems discussed above with respect to FIGS. 1-3, FIG. 4 illustrates an alternative solution. FIG. 4 illustrates a test structure 200. The test structure 200 includes a transistor device or transistor 3. The transistor 3 may be a metal-oxide-semiconductor field effect transistor or a complementary metal-oxide-semiconductor transistor. The transistor 3 may be similar to the transistor 103 shown in FIGS. 1 and 2. It has a gate electrode/gate terminal G, a source electrode/source terminal S, a drain electrode/drain terminal D and a bulk electrode/bulk terminal B. It should be understood that, although no specific electrical connection of the source terminal and the drain terminal are illustrated, these terminals may be connected to further circuitry, if required—instead, for explanatory purposes, such connections are not shown here. In order to provide sufficient protection against plasma-induced damage, two fuses 7, 8 are provided in series. Typically, these two fuses 7, 8 are the same. These two fuses 7, 8 serve for “shorting” the gate to bulk connection of the transistor 3 during a manufacturing process. It should be understood that at least two fuses 7, 8 in series are needed, but that a larger number of fuses, such as n fuses in series, may be provided, where n is an integer number greater than or equal to two. Then, each of the n fuses in series may be the same as fuse 7, 8. Returning to FIG. 4, each of the fuses 7, 8 has two terminals. Correspondingly, in order to be able to contact each terminal of each of the fuses 7, 8 provided in series, an appropriate number of contacting pads is required. FIG. 4 illustrates that a minimum of three contacting pads 5.1, 5.2, 5.3 are provided so as to contact each terminal of the two fuses 7, 8 in series. In case a larger number of fuses, such as n fuses, may be needed in series, correspondingly n+1 contacting pads may be provided so that each terminal of each of the n fuses in series is contacted by one contacting pad. The fuses 7, 8 are ideally realized in the first metallization level to be effective from there already. Any other metallization level may be functional as well, as long as antennae design rules for the wiring are fulfilled thoroughly in this case. Typically, both the first fuse 7 and the second fuse 8 are metal fuses. In practice, silicon fuses or polysilicon fuses may be used and may be similarly effective compared to the first metallization level fuse.

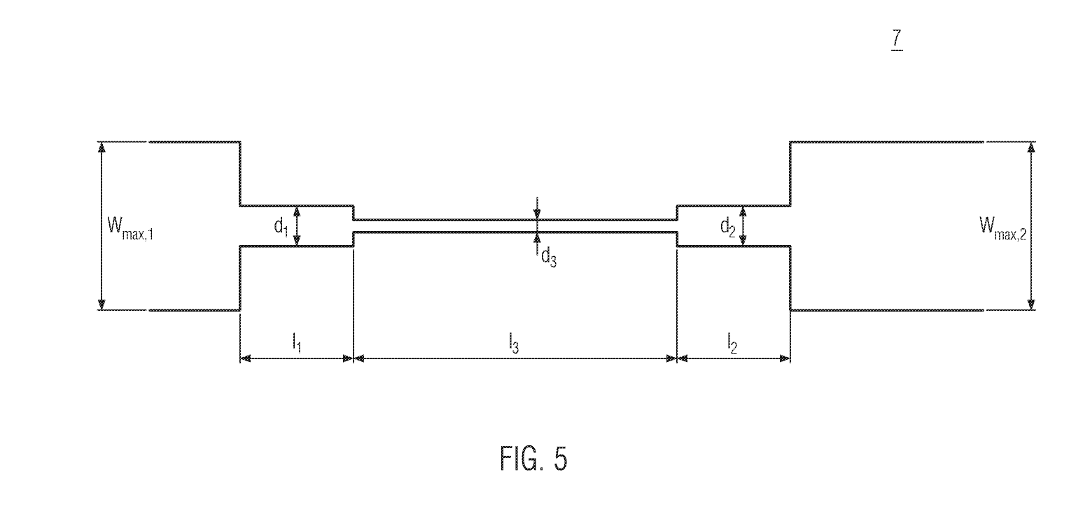

FIG. 5 illustrates an exemplary design of a fuse 7 for the test structure 200 of FIG. 4. As indicated above, the fuse 8 of FIG. 4 may be the same as the fuse 7 of FIGS. 4 and 5. The exemplary design of a fuse 7 of FIG. 5 includes metal fuses to create a test structure protection scheme as shown in FIG. 4. Metal fuses such as the fuses 7, 8 shown in FIGS. 4 and 5 will disrupt/blow once a sufficiently high voltage drives a current exceeding a maximum current through it. Consequently, such fuses as fuses 7, 8 may have very low leakage currents. Using two fuses 7, 8 in series in the above protection scheme may reduce the risk to re-connect upon application of stress voltage significantly, namely after blowing the fuse. A proposed design for application, in particular for 22FDX technology, is illustrated in FIG. 5 depicting a longitudinal cross section through the fuse 7. It should be understood that all values given in the following are exemplary approximate values. The fuse 7 shown in FIG. 5 is symmetrically built, having two terminals on either side of the fuse which may have an approximate maximum width of W_{M}=100-2000 nm. A melting wire or melting part of the fuse is shown in the middle part of FIG. 5, the melting wire having an approximate thickness or diameter of 20-1000 nm, and the melting wire having an approximate length of 0.1-10 μm. Further, the fuse 7 may include an intermediate or connecting part for connecting each end of the melting wire with the respective terminal on the respective side of the fuse. The intermediate or connecting part may have an approximate total length of 100-500 nm and a thickness of about twice the thickness of the melting wire by only a third to a fifth of the thickness of the respective terminal to be connected to the melting wire via the connecting part. Thus, the total length of the melting wire plus two times a connecting part, which typically is the same on either end of the fuse, may be on the order of 1-12 μm.

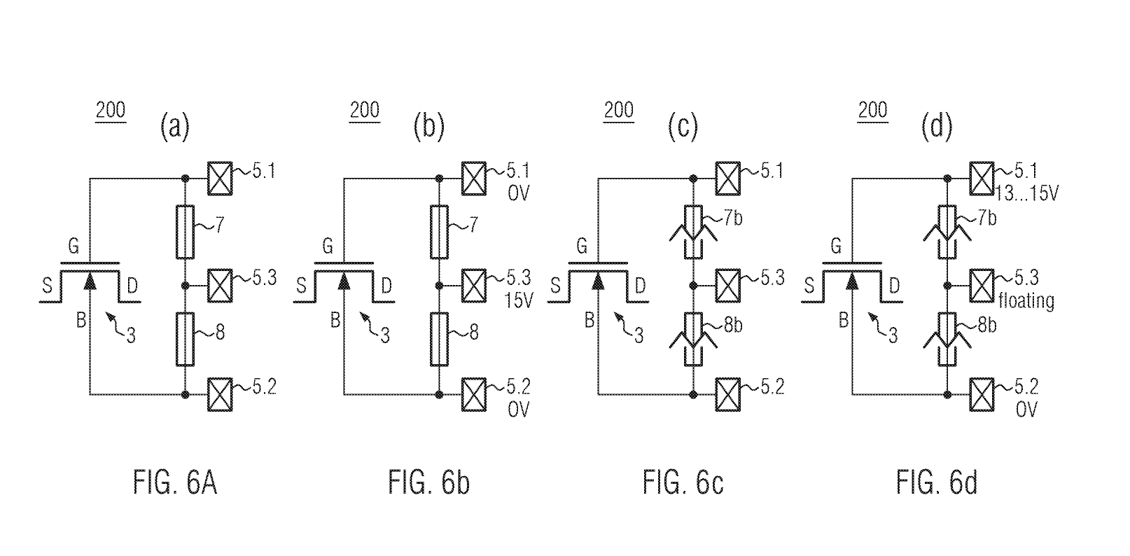

FIGS. 6A-6D illustrate in FIG. 6A the test structure 200 of FIG. 4 after manufacturing. Here the same elements are denoted by the same reference numbers as in FIG. 4. FIG. 6B illustrates the next step just before blowing the fuses 7, 8, when voltages are applied to the contacting pads 5.1, 5.2, 5.3. It should be understood that all values of voltages given in the following are exemplary approximate values. These values may be adjusted individually to the necessary reliability testing overvoltage. The idea is the following: blowing the fuses with the voltage level applied later on during reliability testing ensures the fuses to be “twice as open” as required. This is achieved by the series connection of the two blown fuses and automatically gives sufficient operating margin. As is also shown in FIG. 4 and FIGS. 6A-6B, three contacting pads 5.1, 5.2, 5.3 are provided. The contacting pads 5.1, 5.2, 5.3 are needed in order to blow the two fuses 7, 8 without harming the transistor DUT 3. During blowing of the fuses 7, 8, all three contacting pads 5.1, 5.2, 5.3 need to be biased as shown in FIG. 6B. In FIG. 6B, the first contacting pad 5.1, which is connected to the first terminal of the first fuse 7 and to the gate electrode G of the transistor 3, is biased by 0 V. The second contacting pad 5.2, which is connected to the first terminal of the second fuse 8 and to the bulk electrode B of the transistor 3, is also biased by 0 V. The third contacting pad 5.3, which is connected to the second terminal of the first fuse 7 and the second terminal of the second fuse 8, is biased by 15 V. In this exemplary case, both fuses 7, 8 will be blown, resulting in two blown fuses 7b and 8b as shown in FIGS. 6C and 6D. Having the fuses 7, 8 blown is beneficial for the isolation path and prevents re-connection issues later on. Blowing both fuses 7, 8 with high voltages ensures operation of stress conditions of subsequent reliability stress tests at higher voltages. This is shown in FIG. 6D, which illustrates having the first blown fuse 7b being stressed by a stress voltage of 13-15 V applied to the first contacting pad 5.1. Due to the blowing of each of the fuses 7, 8, the serial connection between the two now-blown fuses 7b, 8b is interrupted such that the third contacting pad 5.3 may be at floating potential, whereas the second contacting pad 5.2 may be biased at 0 V. Thus, for the reliability stress tests of the DUT, there is no limitation of voltage anymore.

In summary a test structure design and a fuse design for use in integrated semiconductor technology, in particular 22FDX technology, is disclosed. The test structure disclosed allows for sufficient overvoltage application for accelerated life test of transistors with higher I/O voltages in modern process technologies. It provides a functional solution for ZG device test structures, in particular in 22FDX technology. In particular, it provides sufficient gate oxide protection during manufacturing against plasma-induced damage. Furthermore, implant changes during technology development are not influencing the protection scheme.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A test structure for a semiconductor device, comprising:
a device under test including a transistor, said transistor having a gate electrode, a source electrode, a drain electrode and a bulk electrode;
a first fuse and a second fuse provided in series, wherein a first terminal of said first fuse is connected to said gate electrode, a first terminal of said second fuse is connected to said bulk electrode, and a second terminal of said first fuse and a second terminal of said second fuse being connected to each other; and
a first input/output pad connected to said first terminal of said first fuse and to said gate electrode of said transistor, a second input/output pad connected to said first terminal of said second fuse and to said bulk electrode of said transistor, and a third input/output pad connected to said second terminal of said first fuse and said second terminal of said second fuse.

2. The test structure of claim 1, wherein said transistor is a metal-oxide-semiconductor field effect transistor or a complementary metal-oxide-semiconductor transistor.

3. The test structure of claim 1, wherein said first fuse and said second fuse are provided in a first metallization level.

4. The test structure of claim 1, wherein said first fuse and said second fuse are provided on another than a first metallization level.

5. The test structure of claim 1, wherein said first fuse and said second fuse are metal fuses.

6. The test structure of claim 5, wherein said first fuse and said second fuse are symmetrical fuses having a melting wire, wherein said melting wire has a thickness or diameter of 20-1000 nm and a length of 0.1-10 μm.

7. A fuse for test structures in integrated semiconductor technology, comprising:
a symmetrical body having two terminals each of a maximum width of 100-2000 nm, said terminals connected by a melting wire of 20-1000 nm thickness and a length of said melting wire of 0.1-10 μm.

8. A semiconductor device with a test structure, comprising:
a power line;
a silicon-on-insulator substrate comprising a semiconductor layer and a semiconductor bulk substrate comprising a doped region; and
a transistor formed in and above said silicon-on-insulator substrate and comprising a gate dielectric formed over said semiconductor layer and a gate electrode formed over said gate dielectric, said transistor having a gate electrode, a source electrode, a drain electrode and a bulk electrode;
wherein said test structure includes:
a device under test including said transistor;
a first fuse and a second fuse provided in series, wherein a first terminal of said first fuse is connected to said gate electrode, a first terminal of said second fuse is connected to said bulk electrode, and a second terminal of said first fuse and a second terminal of said second fuse being connected to each other; and
a first input/output pad connected to said first terminal of said first fuse and to said gate electrode of said transistor, a second input/output pad connected to said first terminal of said second fuse and to said bulk electrode of said transistor, and a third input/output pad connected to said second terminal of said first fuse and said second terminal of said second fuse.

9. The semiconductor device of claim 8, wherein said transistor is a metal-oxide-semiconductor field effect transistor or a complementary metal-oxide-semiconductor transistor.

10. The semiconductor device of claim 8, wherein said first fuse and said second fuse are provided in a first metallization level.

11. The semiconductor device of claim 8, wherein said first fuse and said second fuse are provided on another than a first metallization level.

12. The semiconductor device of claim 8, wherein said first fuse and said second fuse are metal fuses.

13. The semiconductor device of claim 8, wherein said first fuse and said second fuse are symmetrical fuses having a melting wire, wherein said melting wire has a thickness or diameter of 20-1000 nm and a length of 0.1-10 μm.

14. A method of manufacturing a semiconductor device with a test structure, comprising:
providing a silicon-on-insulator semiconductor substrate comprising a semiconductor layer and a semiconductor bulk substrate comprising a doped region;
forming a transistor in and above said silicon-on-insulator substrate, said transistor comprising a gate dielectric formed over said semiconductor layer and a gate electrode formed over said gate dielectric, said transistor having a gate electrode, a source electrode, a drain electrode and a bulk electrode;
providing said test structure including a device under test including said transistor;
providing a first fuse and a second fuse in series, connecting a first terminal of said first fuse to said gate electrode, connecting a first terminal of said second fuse to said bulk electrode, and connecting a second terminal of said first fuse and a second terminal of said second fuse to each other;
providing a first input/output pad connected to said first terminal of said first fuse and to said gate electrode of said transistor;
providing a second input/output pad connected to said first terminal of said second fuse and to said bulk electrode of said transistor; and
providing a third input/output pad connected to said second terminal of said first fuse and said second terminal of said second fuse.

15. The method of claim 14, wherein said transistor is a metal-oxide-semiconductor field effect transistor or a complementary metal-oxide-semiconductor transistor.

16. The method of claim 14, wherein said first fuse and said second fuse are provided in a first metallization level.

17. The method of claim 14, wherein said first fuse and said second fuse are provided on another than a first metallization level.

18. The method of claim 14, wherein said first fuse and said second fuse are metal fuses.

19. The method of claim 14, wherein said first fuse and said second fuse are symmetrical fuses having a melting wire, wherein said melting wire has a thickness or diameter of 20-1000 nm and a length of 0.1-10 μm.

20. The method of claim 14, wherein said transistor device is a triple-well fully depleted silicon-on-insulator field effect transistor (FDSOI FET).
